(19) United States
(12) Patent Application Publication
(10) Pub. No.: US 2007/0268162 A1
(43) Pub. Date: Nov. 22, 2007

(54) Equivalent-time sampling of quasi-repeating bit patterns

(76) Inventors: Martin Viss, Santa Rosa, CA (US); Michael G. Van Grouw, Windsor, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/435,476

(22) Filed: May 17, 2006

(51) Int. Cl. H03M 7/34

(52) U.S. Cl. 341/51

(57) ABSTRACT

An equivalent-time sampling system accommodates quasi-repeating bit patterns by identifying a predetermined sequence of bits within the quasi-repeating bit pattern of a data signal, acquiring a series of samples of the data signal according to the clock signal associated with the data signal, independent of the timing of occurrences of the predetermined sequence of bits within the data signal. The equivalent-time sampling system counts cycles of the clock signal, wherein counting is started at an occurrence of the predetermined sequence of bits within the quasi-repeating bit pattern. The equivalent-time sampling system also synchronizes count values of the counted cycles of the clock signal to samples within the acquired series of samples.

### BACKGROUND OF THE INVENTION

Conventional equivalent-time sampling oscilloscopes are useful for characterizing data signals within digital communication systems that include repeating bit patterns that have constant length. However, in some types of digital communication systems the data signals include bit patterns that do not have a-constant length. The bit patterns in these data signals have varying lengths, and are hereinafter referred to as “quasi-repeating” bit patterns.

FIG. 1 shows an example of a quasi-repeating bit pattern wherein each cycle of the quasi-repeating bit pattern, referred to as a frame, includes a header, a payload, and a sequence of idle bits. The header typically indicates the start of the frame and the payload typically includes a series of data bits. The sequence of idle bits is typically non-repeating and of variable length to maintain timing synchronization with a receiver in a digital communication system. Inserting a varying number of idle bits within each frame to maintain timing synchronization is typically referred to as “bit stuffing”.

In other examples of quasi-repeating bit patterns, the header repeats in each frame, while the series of data bits in the payload varies in both content and length from frame to frame. Alternatively, the header and payload can have constant length, while bit stuffing causes the length of the quasi-repeating bit pattern to vary from frame to frame.

Conventional equivalent-time sampling oscilloscopes are designed to characterize data signals that include repeating bit patterns of constant length. In these sampling oscilloscopes, sample acquisitions are timed according to a trigger that is derived from a deleted sequence of bits within the repeating bit patterns and a priori knowledge of the length of the repeating bit pattern. Accordingly, conventional equivalent-time sampling oscilloscopes have limited ability to accommodate quasi-repeating bit patterns that vary in length from frame to frame. In view of the above, there is a need for an equivalent-time sampling system that can accommodate quasi-repeating bit patterns.

### BRIEF DESCRIPTION OF THE DRAWINGS

FIG. 1 shows an example of a quasi-repeating bit pattern.

FIG. 2 shows an example of an equivalent-time sampling system for quasi-repeating bit patterns according to embodiments of the present invention.

FIG. 3 shows an example of an equivalent-time sampling system for quasi-repeating bit patterns according to alternative embodiments of the present invention.

### DETAILED DESCRIPTION

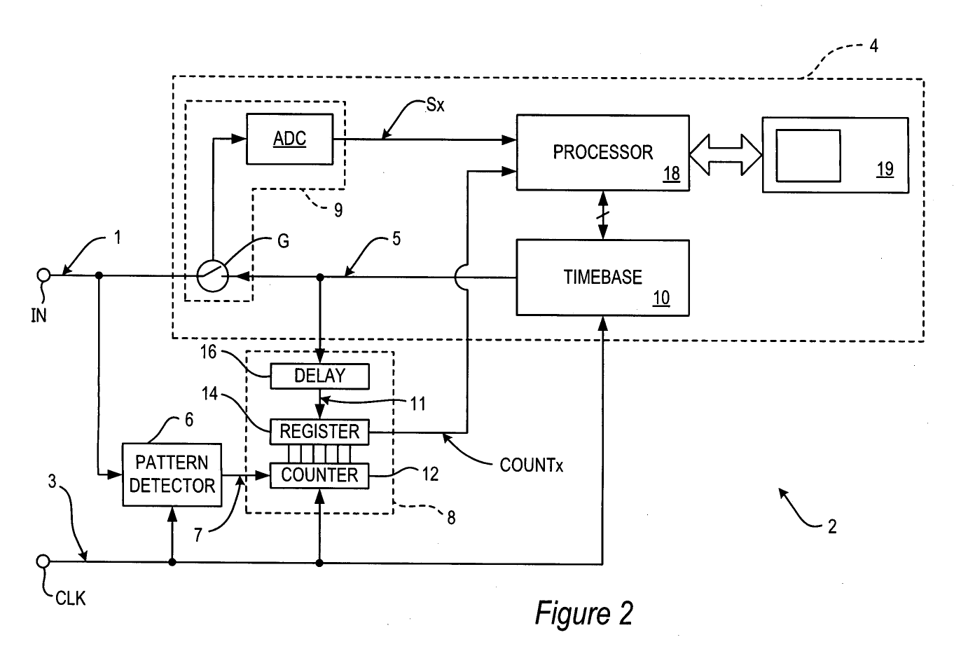

FIG. 2 shows one example of an equivalent-time sampling system, hereinafter “sampling system 2”, according to embodiments of the present invention. For the purpose of illustration, the sampling system 2 is shown including an equivalent-time sampling oscilloscope 4, such as a 86100 series Digital Communications Analyzer, provided by AGILENT TECHNOLOGIES, INC. of Palo Alto, Calif., USA. However, the sampling system 2 alternatively includes any other type of sample acquisition system suitable for acquiring samples Sx of an applied data signal 1 according to a clock signal 3.

The sampling system 2 includes the equivalent-time sampling oscilloscope 4 (hereinafter “sampling oscilloscope 4”), a pattern detector 6 and a timing synchronizer 8. The data signal 1 is applied to a data input IN of the sampling oscilloscope 4, whereas the clock signal 3 is applied to a timing input CLK of the sampling oscilloscope 4. In the example shown in FIG. 2, the clock signal 3 is shown as a signal that is separate from the data signal 1. In alternative examples of the sampling system 2, the clock signal 3 is derived from the data signal 1 using clock recovery (not shown).

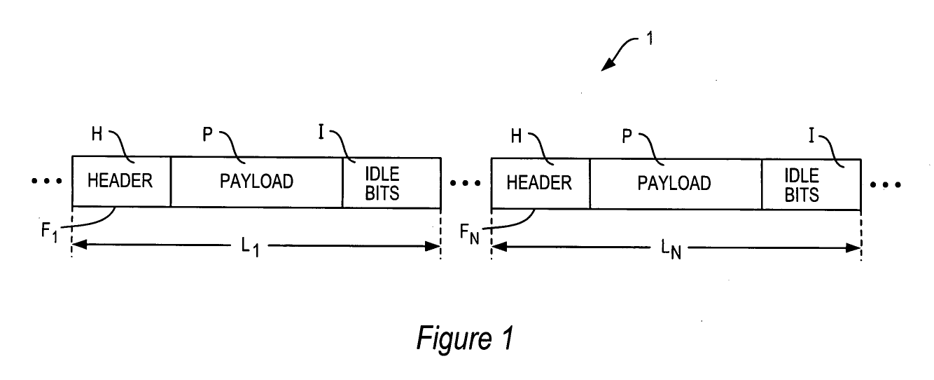

Data signals 1 that can be accommodated by the sampling system 2 include quasi-repeating bit patterns that vary in length. Each cycle of a bit pattern, or frame, of the quasi-repeating bit pattern includes a header H, a payload P, and a sequence of idle bits I, as shown in the example of FIG. 1. In FIG. 1, a frame F₁ is shown having a bit pattern of length L₁, whereas a subsequent frame F_{N} is shown having a bit pattern of length L_{N}, such that L_{N} is not equal to L₁. The header H typically indicates the start of the frame and the payload P typically includes a series of data bits. The sequence of idle bits I is typically non-repeating and of variable length to maintain timing synchronization in a digital communication system within which the data signal 1 may be included.

In some quasi-repeating bit patterns, the header H repeats in each frame, while the series of data bits in the payload P varies in both content and length from frame to frame. Alternatively, the header H and payload P can have constant length, while bit stuffing causes the length of the quasi-repeating bit patterns to vary from frame to frame. Variations in the length of one or more of the header H, the payload P, and the idle bits I can cause the length of the frames F to vary from cycle to cycle thereby forming the quasi-repeating bit pattern.

The data signal 1 including the quasi-repeating bit pattern is applied to a sampler 9 within the sampling oscilloscope 4. The clock signal 3 is applied to a timebase 10 within the sampling oscilloscope 4. The timebase 10 processes or otherwise conditions the clock signal 3 to provide a strobe signal 5 that has timing characteristics that are derived from the clock signal 3. The resulting strobe signal 5 strobes a gating circuit G within the sampler 9 to time sample acquisitions by the gating circuit G and an analog-to-digital converter ADC within the sampler 9. The sample acquisitions by the sampler 9 result in a series of acquired samples Sx at the output of the analog-to-digital converter ADC.

The data signal 1 is also applied to the pattern detector 6 within the sampling system 2. The pattern detector 6 detects the occurrence of a predetermined sequence of bits within the quasi-repeating bit pattern of the data signal 1. In this detection, the pattern detector 6 typically monitors incoming bits of the data signal 1 and compares the incoming bits to a predesignated bit sequence to identify a match between the incoming bits and the predetermined sequence of bits within the header H or other portion of a frame of the quasi-repeating bit pattern of the data signal 1.

In response to the detection of the predetermined bit sequence, the pattern detector 6 provides a reset signal 7 to a counter 12 within the timing synchronizer 8. The reset signal 7 resets the counter 12 to initiate a counting of cycles of the clock signal 3 by the counter 12. The counter 12 continues the counting of cycles of the clock signal 3 until the counter 12 is reset by the reset signal 7, upon the detection of another occurrence of the predetermined sequence of bits within the quasi-repeating bit pattern of the data signal 1.

Since the sampler 9 acquires samples Sx of the data signal 1 according to the strobe signal 5 that is derived from the clock signal 3, whereas the counter 12 is reset according to the reset signal 7 provided by the pattern detector 6, timing synchronization between the acquired samples Sx and the occurrences of the predetermined sequence of bits within the quasi-repeating bit pattern of the data signal 1 is typically lacking. The timing between the acquisitions of the samples Sx and the occurrences of the predetermined sequence of bits within the quasi-repeating bit pattern is further skewed by the varying lengths of the frames within the quasi-repeating bit patterns of the data signal 1.

The timing synchronizer 8 provides for time-alignment, or synchronization, between the acquisitions of the samples Sx and the occurrences of the predetermined bit sequence in the quasi-repeating bit pattern, even though the time between repeated occurrences of the predetermined bit sequence typically varies from frame-to-frame of the quasi-repeating bit pattern. To provide this synchronization, the timing synchronizer 8 pairs count values COUNTx of the counted clock cycles provided by the counter 12 with corresponding samples Sx within the acquired series of samples Sx, where x represents an index for the corresponding samples Sx and count values COUNTx.

The timing synchronizer 8 includes the counter 12, a register 14 and a delay element 16. The delay element 16 provides a delayed version of the strobe signal 5, indicated as delayed strobe 11, to the register 14. In response to an amplitude transition or other designated event or attribute of the strobe signal 5, as delayed by the delay element 16, the delayed strobe 11 latches a corresponding count value COUNTx of the counter 12 into the register 14. The delay element 16 compensates for time delays introduced by the pattern detector 6 and typically introduces a delay to the strobe signal 5 sufficiently long so that the latching of a count value COUNTx of zero into the register 14 by the delayed strobe 11 corresponds to acquisition of a sample of a first bit of the predetermined bit sequence within the quasi-repeating bit pattern of the data signal 1.

The acquired samples Sx and the corresponding count values COUNTx that are latched into the register 14 are provided to a processor 18, typically included in the sampling oscilloscope 4. The processor 18 provides a time-domain representation, or other suitable representation of the data signal 1 on a display or other output device 19 based on the count values COUNTx provided by the register 14 that correspond to the acquired samples Sx the frequency of a clock signal 3, and the values of the acquired samples Sx. An example of the processor 18 and the output device 19 suitable for processing and displaying representations of data signals based on count values, frequency of the clock signal 3, and values of the samples is present in the 86100 series Digital Communications Analyzer, provided by AGILENT TECHNOLOGIES, INC.

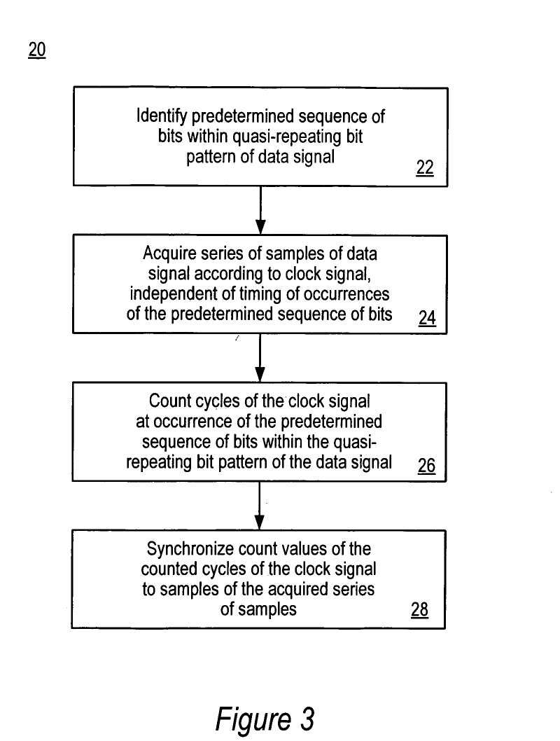

FIG. 3 shows an example of the equivalent-time sampling system 2 implemented by method 20 according to alternative embodiments of the present invention. Step 22 of the method 20 includes identifying a predetermined sequence of bits within the quasi-repeating bit pattern of the data signal 1. Step 24 of the method 20 includes acquiring a series of samples Sx of the data signal 1 according to the clock signal 3 associated with the data signal 1. The timing of the acquisitions of the samples Sx are typically independent of the timing of occurrences of the predetermined sequence of bits within the data signal 1. Step 26 of the method 20 includes counting cycles of the clock signal 3, wherein the counting is started at an occurrence of the predetermined sequence of bits within the quasi-repeating bit pattern of the data signal 1. Step 28 of the method 20 includes synchronizing a count value COUNTx of the counted cycles of the clock signal 3 to each sample within the acquired series of samples Sx. Synchronizing the count values COUNTx of the counted cycles of the clock signal 3 typically includes delaying the strobe signal 5 from a sampler that acquires the series of samples Sx of the data signal 1.

According to some implementations of the method 20, the acquired series of samples Sx and the synchronized count values COUNTx are processed to represent the quasi-repeating bit pattern of the data signal on a display or other output device. According to alternative implementations of the method 20, the method 20 includes monitoring the data signal 1 to identify subsequent occurrences of the predetermined sequence of bits within the quasi-repeating bit pattern and re-starting the counting of the cycles of the clock signal 3 at one or more subsequent occurrences of the predetermined sequence of bits.

While the embodiments of the present invention have been illustrated in detail, it should be apparent that modifications and adaptations to these embodiments may occur to one skilled in the art without departing from the scope of the present invention as set forth in the following claims.

1. A system, comprising:
a pattern detector identifying a predetermined bit sequence within a quasi-repeating bit pattern of an applied data signal;
a sampler acquiring a series of samples of the data signal according to a strobe signal that is independent of the timing of occurrences of the predetermined bit sequence;
a timebase receiving a clock signal associated with the data signal and providing the strobe signal;
a counter counting cycles of the clock signal, wherein the counting is started at each of one or more occurrences of the predetermined bit sequence within the quasi-repeating bit pattern identified by the pattern detector; and
a timing synchronizer synchronizing a corresponding count value of the counted cycles of the clock signal to each sample within the acquired series of samples.

2. The system of claim 1 further comprising a processor processing the acquired series of samples of the data signal and the synchronized corresponding count values to represent the quasi-repeating bit pattern of the data signal on an output device.

3. The system of claim 1 wherein the pattern detector monitors the data signal to identify subsequent occurrences of the predetermined bit sequence within the quasi-repeating bit pattern.

4. The system of claim 2 wherein the pattern detector monitors the data signal to identify subsequent occurrences of the predetermined bit sequence within the quasi-repeating bit pattern.

5. The system of claim 3 wherein the pattern detector resets the counter upon one or more subsequent occurrences of the predetermined bit sequence identified by the pattern detector.

6. The system of claim 4 wherein the pattern detector resets the counter upon one or more subsequent occurrences of the predetermined bit sequence identified by the pattern detector.

7. The system of claim 1 wherein the timing synchronizer delays the strobe signal to synchronize the corresponding count value of the counted cycles of the clock signal to each sample within the acquired series of samples.

8. The system of claim 2 wherein the timing synchronizer delays the strobe signal to synchronize the corresponding count value of the counted cycles of the clock signal to each sample within the acquired series of samples.

9. The system of claim 1 further comprising a clock recovery system that recovers the clock signal from the data signal.

10. A system, comprising:
identifying a predetermined bit sequence within a quasi-repeating bit pattern of a data signal;
acquiring a series of samples of the data signal according to a clock signal associated with the data signal, independent of the timing of occurrences of the predetermined bit sequence;
counting cycles of the clock signal, wherein the counting is started at an occurrence of the predetermined bit sequence within the quasi-repeating bit pattern; and
synchronizing a count value of the counted cycles of the clock signal to each sample within the acquired series of samples.

11. The system of claim 10 further comprising processing the acquired series of samples of the data signal and the synchronized corresponding count values to represent the quasi-repeating bit pattern of the data signal on an output device.

12. The system of claim 10 wherein synchronizing the corresponding count value of the counted cycles of the clock signal to each sample within the acquired series of samples includes delaying a strobe signal from a sampler that acquires the series of samples of the data signal.

13. The system of claim 11 wherein synchronizing the corresponding count value of the counted cycles of the clock signal to each sample within the acquired series of samples includes delaying a strobe signal from a sampler that acquires the series of samples of the data signal.

14. The system of claim 10 further comprising monitoring the data signal to identify subsequent occurrences of the predetermined bit sequence within the quasi-repeating bit pattern.

15. The system of claim 11 further comprising monitoring the data signal to identify subsequent occurrences of the predetermined bit sequence within the quasi-repeating bit pattern.

16. The system of claim 12 further comprising monitoring the data signal to identify subsequent occurrences of the predetermined bit sequence within the quasi-repeating bit pattern.

17. The system of claim 14 further comprising re-starting the counting of the cycles of the clock signal upon one or more subsequent occurrences of the predetermined bit sequence.

18. The system of claim 15 further comprising re-starting the counting of the cycles of the clock signal upon one or more subsequent occurrences of the predetermined bit sequence.

19. The system of claim 16 further comprising re-starting the counting of the cycles of the clock signal upon one or more subsequent occurrences of the predetermined bit sequence.

20. The system of claim 10 wherein the clock signal is recovered from the data signal using clock recovery.
